(19) United States
(12) Patent Application Publication
(10) Pub. No.: US 2012/0162906 A1
(43) Pub. Date: Jun. 28, 2012

(54) DATA CENTER AND ITS CONFIGURATION ARRANGEMENTS AND CONFIGURATION UNITS OF ELECTRONIC DEVICE ASSEMBLIES AND AIR CONDITIONERS

(75) Inventor: Ben-Chiao Jai, Taoyuan Hsien (TW)

(73) Assignee: DELTA ELECTRONICS, INC., Taoyuan Hsien (TW)

(21) Appl. No.: 13/076,204

(22) Filed: Mar. 30, 2011

(30) Foreign Application Priority Data
Dec. 24, 2010 (TW) 099145697

(51) Int. Cl. H05K 7/20

(52) U.S. Cl. 361/679.53; 361/692

(57) ABSTRACT

Disclosed is a data center and its configuration arrangements and configuration units of electronic device assemblies and air conditioners, in which the configuration arrangements of electronic device assemblies and air conditioners includes an air conditioner and a plurality of electron device assemblies. The air conditioner includes an intake and a corresponding opposite outtake and the electronic device assemblies are mounted around to form a block. Each electronic device assembly includes an air inlet and a corresponding air outlet. The air conditioner is mounted in the block and partitions the block into a first sector and a second which are both shaped as a polygon. The intake and the outtake of the air conditioner respectively face the first sector and the second sector, and the electronic device assembly adjacent to the first sector faces the first sector with its air outlet and the electronic device assembly adjacent to the second sector faces the second sector with its air inlet.

### FIELD OF THE INVENTION

The invention is related to a data center and the configuration arrangement of electronic device assemblies and air conditioners for use in the data center, and more particularly to a data center and the configuration arrangement of electronic device assemblies and air conditioners for use in the data center that can improve the heat-dissipating efficiency of the air conditioners.

### MOTIVE OF THE INVENTION

With the advancement of technology, various electronic devices have been developed in order to meet user's demands for high-speed data processing and vast data processing quantity. The examples of electronic devices with high-speed data processing and vast data processing quantity include computers, servers, and storage devices. These electronic devices may be interconnected so as to allow data to be partitioned and distributed among the electronic devices for being processed. The processed data chunks are collected and retained. Such configuration arrangement for electronic devices can accomplish the task that is not able to be accomplished by a single electronic device. Data center is a place where a large number of electronic devices are gathered for data processing. However, if the heat generated during operation of the electronic devices can not be immediately dissipated, a negative effect will be induced. Hence, it is important to properly condition the operating environment of the data center.

Referring to FIG. 1, the plan view showing the configuration arrangement of a data center according to the prior art is shown. As shown in FIG. 1, a plurality of electronic devices 122 of a data center 1 is mounted in the rack 121. A plurality of racks 121 such as the six racks shown in FIG. 1 are linked to constitute an electronic device assembly 12. A plurality of electronic device assemblies 12 such as the four electronic device assemblies which are arranged in parallel as shown in FIG. 1 are mounted in the center of the compartment 13. A plurality of air conditioners 11 are mounted in the side area of the compartment 13 for absorbing the heat and providing cooling air after the heat exchange is carried out. The cooling air is used to cool down the electronic device assemblies 12.

Nonetheless, the air conditioners 11 are generally mounted in the side area of the compartment 13. The cooling air provided by the air conditioners 11 will be warmed up gradually with the increment of the travelling distance of the cooling air and the cool airflow will be dispersed gradually. In other words, the heat-dissipating effect of the electronic device assembly 12 located near the air outlet of the air conditioner 11 is better than the electronic device assembly 12 located distantly from the air outlet of the air conditioner 11. Therefore, the heat-dissipating effect of the electronic device assemblies 12 is not uniform for the electronic device assemblies. In order to let the electronic device assembly 12 located distantly from the air conditioner 11 to attain the desired heat-dissipating effect, the temperature of the cool airflow provided by the air conditioner 11 is descended. However, such measure will cause energy loss and increase the cost. In addition, as the air conditioners 11 and the electronic device assemblies are arranged in an open environment, the cool airflow provided by the air conditioners 11 is difficult to be concentrated to circulate in the electronic device assemblies 12. This is because part of the cool airflow will result in short circulation and return to the air conditioners 11 before the cool airflow flows through the electronic device assemblies. The heat airflow generated by the electronic device assemblies 12 will disperse and is difficult to be concentrated to exchange heat with the cool airflow of the air conditioners 11. These factors will seriously lower the efficiency of the air conditioners 11. As the heat-dissipating effect of the electronic device assemblies 12 are not uniformly distributed, the operation of the data center 1 will be affected.

In view of the foregoing problems, it is intended to develop a data center and the configuration arrangement of electronic device assemblies and air conditioners for use in the data center that can address the foregoing problems.

### SUMMARY OF THE INVENTION

An object of the invention is to provide a data center and the configuration arrangement of electronic device assemblies and air conditioners for use in the data center. The configuration arrangement of electronic device assemblies and air conditioners employs a substantially closed area enclosed by the sides of the electronic device assemblies and air conditioners. The configuration arrangement of electronic device assemblies and air conditioners includes at least two configuration units of electronic device assemblies and air conditioners. The data center includes a plurality of electronic device assemblies and air conditioners having a plurality of interlaced relatively high temperature areas and relatively low temperature areas. Therefore, the heat airflow generated by the electronic device assemblies can be collectively directed to the air conditioners for heat exchange and the cool airflow generated by the air conditioners can be directly introduced into the electronic device assemblies, thereby facilitating the reduction of the path of airflow circulation. As a result, the problems encountered by the prior art that the heat-dissipating effect is not uniform among the electronic device assemblies and air conditioners and the heat-dissipating efficiency of the air conditioners is low as a result of the open configuration of the electronic device assemblies and air conditioners can be solved.

To this end, the invention provides a configuration arrangement of electronic device assemblies and air conditioners for use in a data center. The configuration arrangement includes a plurality of electronic device assemblies and an air conditioner. The air conditioner includes an intake and an outtake respectively mounted on opposite sides of the air conditioner. The electronic device assemblies are mounted around to form a block, and each electronic device assembly includes an air outlet and an air inlet. The air conditioner is mounted in the block, and the block is partitioned into a first sector and a second sector, both of which are substantially shaped in polygon. The intake and the outtake of the air conditioner respectively face the first sector and the second sector. The electronic device assembly adjacent to the first sector faces the first sector with the air inlet, and the electronic device assembly adjacent to the second sector faces the second sector with the air outlet

To this end, the invention provides a configuration unit of electronic device assemblies and air conditioners for use in a configuration arrangement of electronic device assemblies and air conditioners and includes an air conditioner and a plurality of electronic device assemblies. The air conditioner includes an intake and a corresponding outtake. The electronic device assemblies are mounted around the intake or the outtake of the air conditioner in order to form a sector with the air conditioner, in which the sector is shaped in polygon. Each electronic device assembly includes an air inlet and an air outlet. When the electronic device assemblies are mounted around the intake of the air conditioner, the air outlet of the electronic device assemblies faces the sector. When the electronic device assemblies are mounted around the outtake of the air conditioner, the air inlet of the electronic device assemblies faces the sector.

To this end, the invention provides a data center including a compartment and a plurality of configuration arrangement of electric device assemblies and air conditioners mounted in the compartment. Each configuration arrangement of electric device assemblies and air conditioners includes a plurality of electric device assemblies and an air conditioner. The electric device assemblies are mounted around to form a block, and the air conditioner is mounted in the block to partition the block into a first sector and a second sector which are substantially shaped in polygon. Any two adjacent configuration arrangement of electric device assemblies and air conditioners share an electronic device assembly, and the first sectors and the second sectors are interlaced.

Now the foregoing and other features and advantages of the present invention will be best understood through the following descriptions with reference to the accompanying drawings, wherein:

### BRIEF DESCRIPTION OF THE DRAWINGS

FIG. 1 is a plan view showing the configuration arrangement of a data center according to the prior art;

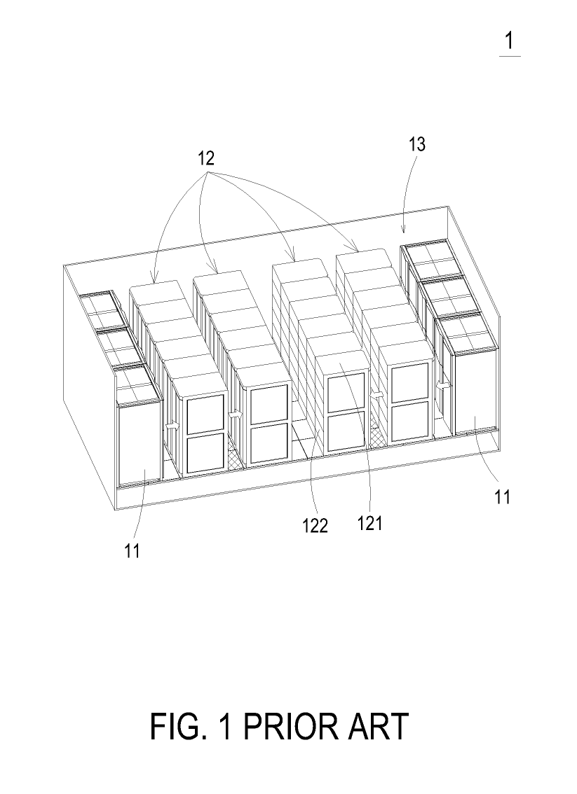

FIG. 2 is a plan view showing the configuration arrangement of the electronic device assemblies and air conditioners according to a first embodiment of the invention

FIG. 3A is a top view of the data center incorporating the configuration arrangements of the electronic device assemblies and air conditioners of FIG. 2;

FIG. 3B illustrates the airflow circulation of the data center of FIG. 3A;

FIG. 4A is a top view of the data center according to a second embodiment of the invention;

FIG. 4B is a schematic diagram showing the airflow circulation in the data center of FIG. 4A;

FIG. 5 is a plan view showing the configuration arrangement of the electronic device assemblies and air conditioners according to a third embodiment of the invention;

FIG. 6 is a top view of the data center incorporating the configuration arrangements of the electronic device assemblies and air conditioners of FIG. 5; and

FIG. 7 is a top view of the data center according to a fourth embodiment of the invention.

### DETAILED DESCRIPTION OF THE PREFERRED EMBODIMENT

Several exemplary embodiments embodying the features and advantages of the present invention will be expounded in following paragraphs of descriptions. It is to be realized that the present invention is allowed to have various modification in different respects, all of which are without departing from the scope of the present invention, and the description herein and the drawings are intended to be taken as illustrative in nature, and are not intended to be taken as a confinement to limit the invention.

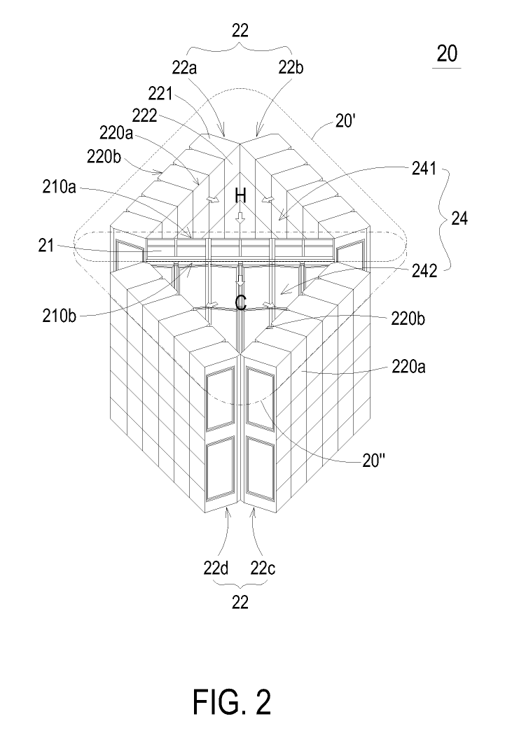

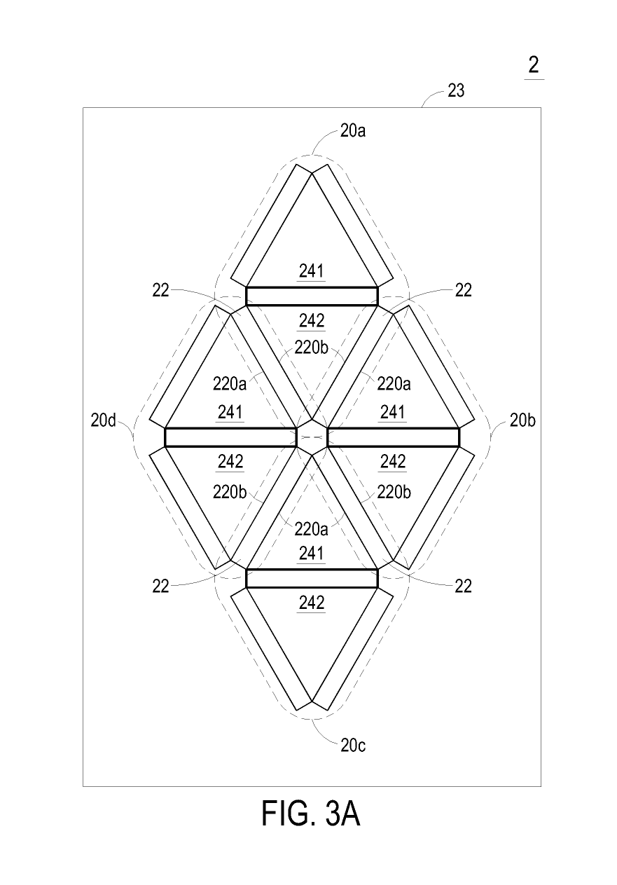

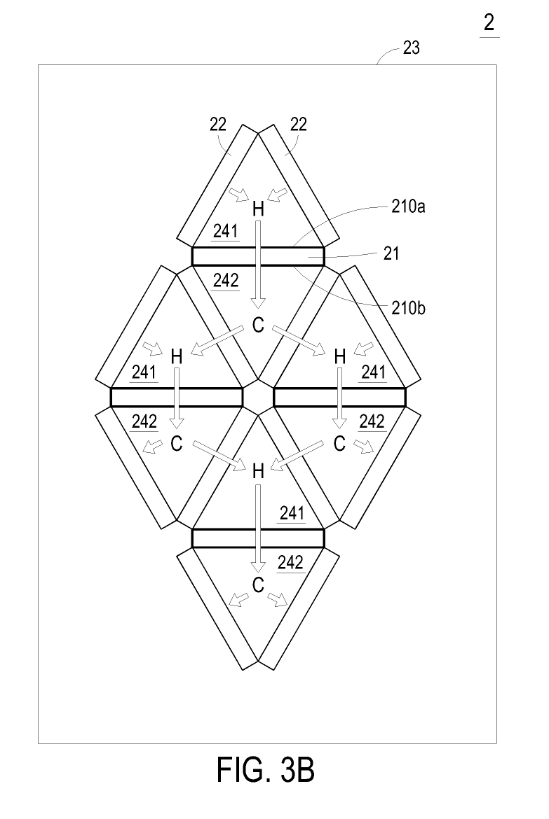

Referring to FIG. 2, the plan view showing the configuration arrangement of the electronic device assemblies and air conditioners according to a first embodiment of the invention. As shown in FIG. 2, the configuration arrangement 20 of the electronic device assemblies and air conditioner is applicable to a data center 2 shown in FIG. 3A, and includes an air conditioner 21 and a plurality of electronic device assemblies 22. In the present embodiment, the configuration arrangement 20 of the electronic device assemblies and air conditioners includes four electronic device assemblies 22a-22d, in which the first electronic device assembly 22a and the second electronic device assembly 22b are linked with each other with the lengthwise edges thereof, and the lengthwise edges of the first electronic device assembly 22a and the second electronic device assembly 22b are linked with an angle of, for example, 60 degree. The third electronic device assembly 22c and the fourth electronic device assembly 22d are linked with each other with the lengthwise edges thereof, and the lengthwise edges of the third electronic device assembly 22c and the fourth electronic device assembly 22d are linked with an angle of, for example, 60 degree. The widthwise edge of the first electronic device assembly 22a and the widthwise edge of the fourth electronic device assembly 22d are located proximately and an angle is formed substantially at the intersection of the extension of the widthwise edges. The angle may be 120 degree. Likewise, the widthwise edge of the second electronic device assembly 22b and the widthwise edge of the third electronic device assembly 22c are located proximately and an angle is formed substantially at the intersection of the extension of the widthwise edges. The angle may be 120 degree. Therefore, the electronic device assemblies 22a-22d are mounted around and thus a block 24 which is substantially shaped as a quadrilateral is formed. For example, the block 24 shown in FIG. 2 is a diamond-shaped block. The air conditioner 21 is mounted in the block 24 and is preferably placed along the diagonal of the block 24. In this manner, the air conditioner 21 partitions the block 24 into two sectors which are substantially shaped as a polygon, i.e. a first sector 241 and a second sector 242. In the present embodiment, the length of the air conditioner 21 is substantially equal to the length of the electronic device assembly 22. Therefore, both of the first sector 241 and the second sector 242 may substantially be a regular triangle.

Referring to FIG. 2 again, the air conditioner 21 of the present embodiment is a side-blown air conditioner and includes an intake 210a and an outtake 210b which are oppositely mounted in the air conditioner 21. For example, the intake 210a and the outtake 210b are respectively mounted on opposite sides on the lengthwise direction and the heightwise direction. In other words, the flowing direction of the airflow may penetrate the lengthwise side and the heightwise side of the air conditioner 21. The electronic device assembly 22, for example, the first electronic device assembly 22a, includes a plurality of interconnected racks 221, such as the six racks 221 shown in FIG. 2. Each rack 221 may accommodate a plurality of electronic devices 222 which may be computers, servers, or storage devices. As the electronic devices 222 generate heat during operation, the first electronic device assembly 22a includes an air inlet 220a and an air outlet 220b for dissipating the heat for the first electronic device assembly 22a. In the present embodiment, the air inlet 220a and the air outlet 220b are respectively mounted on the opposite sides of the first electronic device assembly 22a. For example, the air inlet 220a and the air outlet 220b are respectively mounted on opposite sides parallel to the lengthwise direction and the heightwise direction of the first electronic device assembly 22a. The configuration of the electronic device assemblies 22b-22d is similar to that of the first electronic device assembly 22a, and it is not intended to give details on the configuration of the electronic device assemblies 22b-22d herein.

As shown in FIG. 2, when the air conditioner 21 and the electronic device assemblies 22 are configured, the air conditioner 21 may allow its intake 210a to face the first sector 241. As the outtake 210b is opposite to the intake 210a, the outtake 210b faces the second sector 242. The electronic device assemblies 22a and 22b which are adjacent to the first sector 241 are allowed their outtakes 220a to face the first sector 241, and the electronic device assemblies 22c and 22d which are adjacent to the second sector 242 are allowed their intakes 220b to face the second sector 242.

Referring to FIG. 2 again, the configuration arrangement 20 of the electronic device assemblies and air conditioners may be substantially implemented by the configuration unit 20′ of the electronic device assemblies 22a and 22b and the air conditioner 21 and the configuration unit 20″ of the electronic device assemblies 22a and 22b and the air conditioner 21, as indicated by the dotted line. The configuration unit 20′ includes the air conditioner 21 and the first electronic device assembly 22a and the second electronic device assembly 22b mounted around the intake 210a of the air conditioner 21. Therefore, a first sector 241 which is substantially shaped as a triangle is formed by the air conditioner 21 and the first electronic device assembly 22a and the second electronic device assembly 20b, and both of the first electronic device assembly 22a and the second electronic device assembly 20b face the first sector 241 with the air outlets 220a. The configuration unit 20″ includes the air conditioner 21 and the third electronic device assembly 22c and the fourth electronic device assembly 22d mounted around the intake 210b of the air conditioner 21. Therefore, a second sector 242 which is substantially shaped as a triangle is formed by the air conditioner 21 and the third electronic device assembly 22c and the fourth electronic device assembly 22d, and both of the third electronic device assembly 22c and the fourth electronic device assembly 22d face the second sector 241 with the air inlets 220b. Also, the configuration unit 20′ and the configuration unit 20″ share a common air conditioner 21.

As the electron devices 222 of the electronic device assemblies 22 of the configuration arrangement 20 generate heat during operation, the first electronic device assembly 22a and the second device assembly 22b adjacent to the first sector 241 may discharge heat airflow H to the first sector 241 through the air outlet 220a. In other words, the first sector 241 is substantially a relatively hot sector. As the air conditioner 21 faces the first sector 241 with the intake 210a, the heat airflow H can be absorbed by the air conditioner 21 and exchange heat with the cooling device (not shown) located within the air conditioner 21. Afterwards, a cool airflow C may be discharged to the second sector 242 by the blower (not shown) through the outtake 210b. Therefore, the second sector 242 is a relative cool sector compared to the first sector 241. As the third electronic device assembly 22c and the fourth electronic device assembly 22d face the second sector 242 with the air inlets 220b, the third electronic device assembly 22c and the fourth electronic device assembly 22d may receive the cool airflow C through the air inlets 220b to facilitate the heat dissipation for the electronic device assembly 22. As the configuration unit 20′ and the configuration unit 20″ share a common air conditioner 21 and the electronic device assemblies 22a and 22b of configuration unit 20′ are mounted around the intake 210a of the air conditioner 21 and the electronic device assemblies 22c and 22d of configuration unit 20″ are mounted around the outtake 210a of the air conditioner 21, the airflow may be circulated among between the configuration unit 20′ and the configuration unit 20″ by the air conditioner 21.

It can be known from the above descriptions that as the configuration unit 20′ employs the electronic device assemblies 22a and 22b which are mounted around the intake 210a of the air conditioner 21 to provide a guiding effect for the airflow, the heat airflow H is prohibited from being dispersed and is concentrated to be guided to the intake 210a of the air condition for heat exchange. As the configuration unit 20″ employs the electronic device assemblies 22c and 22d which are mounted around the outtake 210b of the air conditioner 21 to provide a guiding effect for the airflow, the cool airflow C which is generated by heat exchange is prohibited from being dispersed and is flowed to air inlets of the electronic device assemblies 22c and 22d. In the manner, the problem that the cool airflow can not be concentrated to flow through the electronic device assemblies 12 as a result of the open configuration of the electronic device assemblies 12 can be solved. As the air conditioner 21 is mounted in the block 24 formed by the surrounding placement of the electronic device assemblies 22 and partitions the block 24 into a first sector 241 and a second sector 242, the intake 210a of the air conditioner 21 faces the first sector 241 and the outtake 210b of the air conditioner 21 faces the second sector 242. Thus, the heat airflow H discharged by the electronic device assemblies 22a and 22b which are adjacent to the first sector 241 can enter the intake 210a of the air conditioner 21 to exchange heat within the air conditioner. Furthermore, the cool airflow C generated by heat exchange in the air conditioner 21 can flow to the second sector 242 through the outtake 210b and enter the electronic device assemblies 22c and 22d which are adjacent to the second sector 242 through the air inlets 220b of the electronic device assemblies 22c and 22d. In this manner, the circulation paths of the heat airflow and the cool airflow can be shortened, thereby solving the problem encountered by the prior art that the circulation path of the airflows is overlong to cause the reduction in the efficiency of the air conditioner.

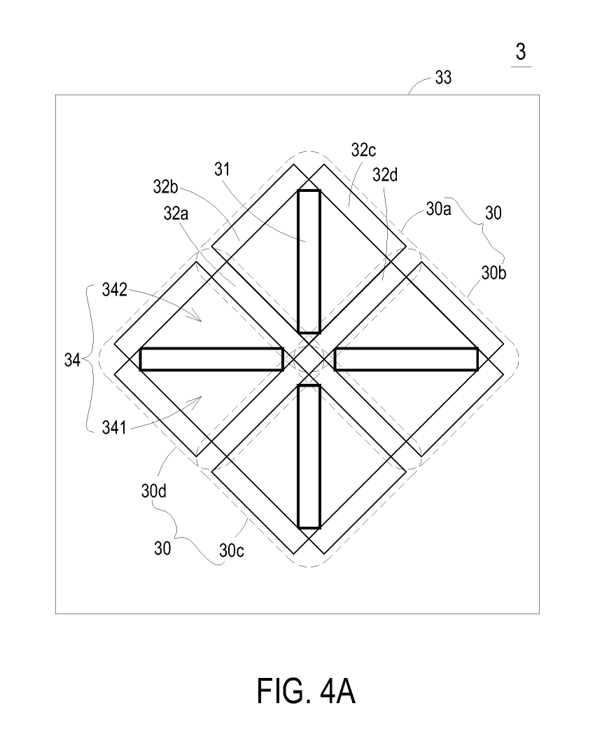

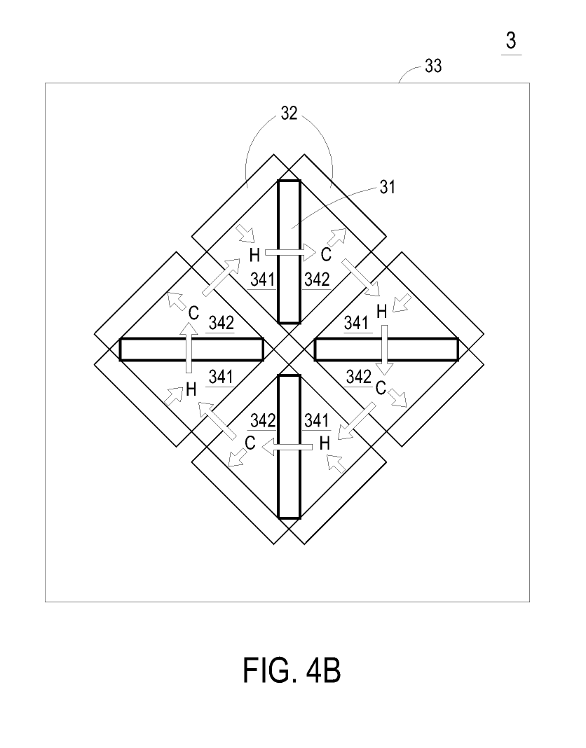

The configuration arrangement 20 of the electronic device assemblies and air conditioners is applicable to the data center 2 and may be expanded depending on the data center's demands. Referring to FIGS. 2 and 3A, in which FIG. 3A shows the top view of the data center incorporating the configuration arrangements of the electronic device assemblies and air conditioners of FIG. 2. For the sake of illustration, the air conditioners 21 are depicted in bold lines in FIGS. 3A and 4A in order to be distinguished from the electronic device assemblies 22. As shown in FIG. 3A, the data center 2 includes a compartment 23 and a plurality of configuration arrangements 20 of electronic device assemblies and air conditioners. The configuration arrangements 20a-20d shown in FIG. 3A include electronic device assembly and air conditioners arranged clockwise in the compartment 23. The configuration arrangements 20a-20d shown in FIG. 3A are substantially the same with the configuration arrangements 20 shown in FIG. 2. Any two adjacent configuration arrangements share a common electronic device assembly 22 for allowing the air inlet 220b and the air outlet 220a of the electronic device assembly 22 to respectively face the adjacent second sector 242 and the adjacent first sector 241. For example, the configuration arrangement 20a shares a common electronic device assembly 22 with the configuration arrangement 20b. The configuration arrangement 20c shares a common electronic device assembly 22 with the configuration arrangement 20d. The configuration arrangement 20a shares a common electronic device assembly 22 with the configuration arrangement 20d. Thus, the configuration arrangements 20a-20d are configured in a hive topology, and the first sectors 241 and the second sectors 242 are interlaced. In other words, the sector adjacent to the first sector 241 must be the second sector 242 in the compartment, and vice versa.

Referring to FIGS. 3A and 3B, in which FIG. 3B illustrates the airflow circulation of the data center of FIG. 3A. As the data center 2 is operating, the electronic device assembly 22 of the configuration arrangement 20a of the air conditioner which is adjacent to the first sector 241 will generate a heat airflow H. The heat airflow H may enter the air conditioner 21 through the intake 210a of the air conditioner 21 and a cool airflow C is discharged to the second sector 242 after the heat exchange is completed. Thus, the cool airflow C may enter the air inlet 220b of the electronic device assembly 22 which is adjacent to the second sector 242 to dissipate the heat generated by the electronic device assembly 22. The heat airflow H after the heat exchange is completed may be discharged to the first sector 241 through the air outlet 220a of the electronic device assembly 22. Next, the heat airflow H exchanges heat in the air conditioner 21 of the configuration arrangements 20b and 20d to generate a cool airflow C which is discharged to the second sector 242. Next, the cool airflow C may enter the electronic device assembly 22 which is adjacent to the second sector 242 and a heat airflow H is generated by heat exchange. The heat airflow H is gathered at first sector 241 to exchange heat with the air conditioner 21 of the configuration arrangement 20c to generate a cool airflow C. The cool airflow C is then flowed to the second sector 242. Thus, an airflow circulation is created between the configuration arrangements 20.

It can be understood from the above descriptions that as the configuration arrangements 20 expands, the electronic assemblies 22 may be configured in a hive topology instead of the conventional open configuration, thereby forming an airflow circulation with the adjacent configuration arrangement 20 of the electronic device assemblies and air conditioners. Therefore, the path of the airflow circulation is shortened to overcome the problems encountered by the prior art that the heat-dissipating effect is poor as a result of an overlong travelling distance for the airflow circulation. Moreover, each electronic device assembly is equidistantly spaced from each air conditioner, thereby uniformizing the heat-dissipating effect of the electronic device assemblies 22.

Certainly, the invention can be attained with various embodiments. Referring to FIG. 4A, a top view of the data center according to a second embodiment is shown. In the present embodiment, the data center 3 also includes a plurality of configuration arrangements 30 of electronic device assemblies and air conditioners. For example, the configuration arrangements 30a-30d of electronic device assemblies and air conditioners are mounted in the compartment 33 and are similar to the configuration arrangements 20 of electronic device assemblies and air conditioners shown in the first embodiment of FIG. 2. All of the configuration arrangements 30a-30d of electronic device assemblies and air conditioners include an air conditioner 31 and a plurality of electronic device assemblies 32 such as the electronic device assemblies 32a-32d. However, the quadrilateral block 34 formed by the enclosure of the electronic device assemblies 32a-32d is substantially shaped as a rectangle, and the length of the air conditioner 31 is substantially larger than the length of the electronic device assembly 32. The air conditioner 31 is mounted in the block 34 and partitions the block 34 into a first sector 341 and a second sector 342 which are both shaped as an isosceles triangle. Any two adjacent configuration arrangements 30a-30d share a common electronic device assembly 32, and the first sectors 341 and the second sectors 342 are interlaced, as shown in FIG. 4B. The configuration relationship of FIG. 4 is similar to the configuration relationship of FIG. 3A. For example, the configuration arrangement 30a and the configuration arrangement 30b share a common electronic device assembly 32.

Referring to FIG. 4B, a schematic diagram showing the airflow circulation in the data center of FIG. 4A is shown. As can be rapidly known from FIG. 4B that any two adjacent assemblies 30 of electronic device assemblies and air conditioners substantially share one electronic device assembly 32 and a plurality of first sectors 341 and second sectors 342 are interlaced, airflow circulation is created among the configuration arrangements of electronic device assemblies and air conditioners. In addition, each electronic device assembly is equidistantly spaced from the air conditioner, thereby uniformizing the heat-dissipating effect of the electronic device assembly 32. In this manner, the efficiency of the air conditioner 32 is improved and the overall heat-dissipating effect of the data center is enhanced.

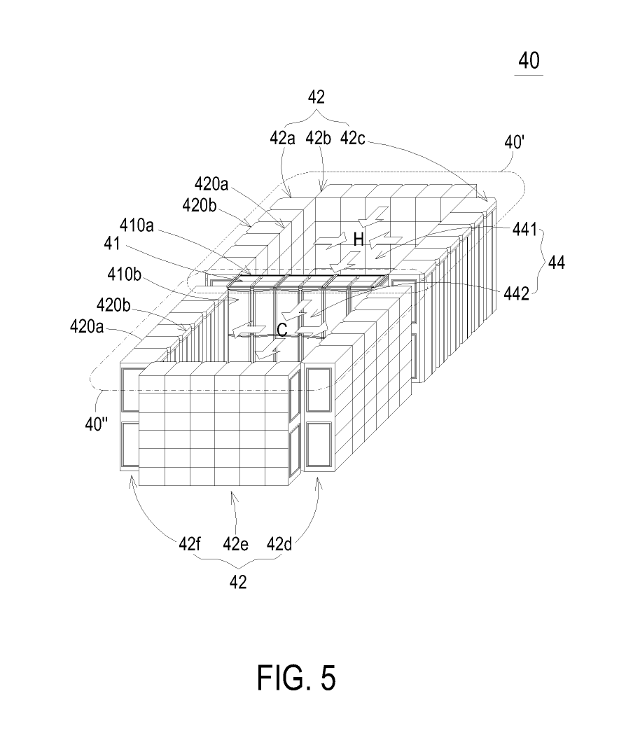

Referring to FIG. 5, the plan view showing the configuration arrangements of the electronic device assemblies and air conditioners according to a third embodiment of the invention. As shown in FIG. 5, the configuration arrangement 40 of the electronic device assemblies and air conditioners includes an air conditioner 41 and a plurality of electronic device assemblies 42 such as the electronic device assemblies 42a-42f. The second electronic device assembly 42b is respectively connected to one side of the first electronic device assembly 42a and one side of the third electronic device assembly 42c with two opposite edges. The fifth electronic device assembly 42e is respectively connected to one side of the fourth electronic device assembly 42d and one side of the sixth electronic device assembly 42f with two opposite edges. The other side of the first electronic device assembly 42a and the other side of the sixth electronic device assembly 42f are located proximate with each other, and the other side of the third electronic device assembly 42c and the other side of the fourth electronic device assembly 42d are located proximate with each other, thereby the electronic device assemblies 42 are mounted around to form a block 44 which is shaped as a rectangle. The air conditioner 41 is mounted in the block 44 and is preferably between the junction of the first electronic device assembly 42a and the sixth electronic device assembly 42f and the junction of the third electronic device assembly 42c and the fourth electronic device assembly 42d. In this manner, the block 44 is symmetrically partitioned into two rectangular sectors, i.e. a first sector 441 and a second sector 442. The air conditioner 41 includes an intake 410a and an outtake 410b respectively mounted on opposite sides of the air conditioner 41. The air inlet 410a and the air outlet 410b respectively face the first sector 441 and the second sector 442. Each electronic device assembly 42 includes an air outlet 420a and an air inlet 420b. The electronic device assemblies 42a-42c which are adjacent to the first sector 441 face the first sector 441 with air outlets 420a, and their air inlets 420b face outwardly. The electronic device assemblies 42d-42f which are adjacent to the second sector 442 face the second sector 442 with air inlets 420b, and their air outlets 420a face outwardly.

Likewise, the configuration arrangement 40 of the electronic device assemblies and air conditioners may be substantially implemented by the configuration unit 40′ of the electronic device assemblies and the air conditioner and the configuration unit 40″ of the electronic device assemblies and the air conditioner, in which the configuration unit 40′ and the configuration unit 40″ share a common air conditioner 41. The configuration unit 40′ includes electronic device assemblies 42a-42c mounted around the intake 410a of the air conditioner 41. The surrounding placement of the electronic device assemblies 42a-42c forms a first sector 441 and the electronic device assemblies 42a-42c face the first sector 441 with the air outlet 420a. The configuration unit 40″ includes electronic device assemblies 42d-42f mounted around the outtake 410b of the air conditioner 41. The surrounding placement of the electronic device assemblies 42d-42f forms a second sector 442 and the electronic device assemblies 42d-42f face the second sector 442 with the air inlet 420b. Therefore, when the configuration arrangement 40 is operating, the heat airflow H generated by the electronic device assemblies 42a-42c may be discharged to the first sector 441 through the air outlet 420a and enter the air conditioner 41 through the intake 410a for heat exchange. The cool airflow C generated by the heat exchange may be discharged to the second sector 442 through the outtake 410b and enter the electronic device assemblies 42d-42f through the air inlet 420b, thereby dissipating the heat generated by the electronic device assemblies 42d-42f.

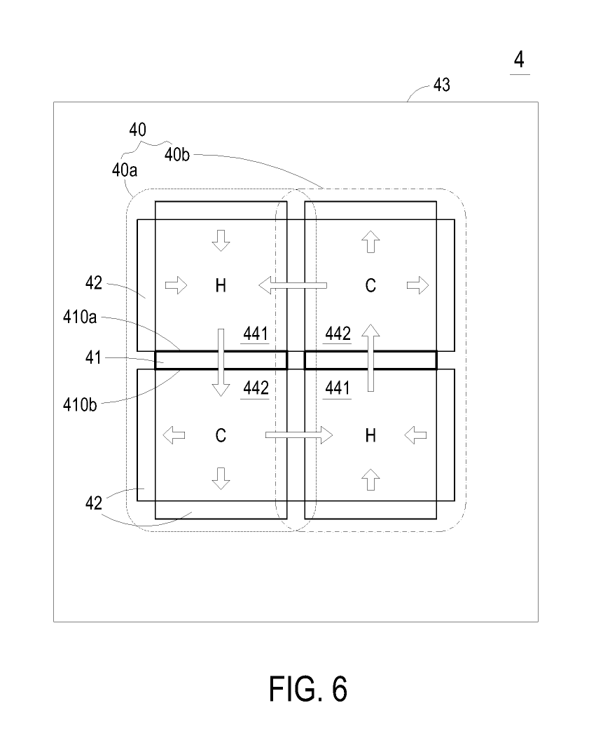

Certainly, the configuration arrangement 40 of electronic device assemblies and air conditioners may be expanded depending on the data center's demands. Referring to FIGS. 5 and 6, in which FIG. 6 is a top view of the data center incorporating the configuration arrangements of the electronic device assemblies and air conditioners of FIG. 5. As shown in FIG. 6, the data center 4 includes a compartment 43 and a plurality of configuration arrangements 40 of electronic device assemblies and air conditioners mounted in parallel in the compartment 43. Two adjacent configuration arrangements 40 share a common electronic device assembly 42. For example, the data center 4 includes configuration arrangements 40a and 40b of electronic device assemblies and air conditioners, in which the configuration arrangements 40a and the configuration arrangements 40b share a common electronic device assembly 42. In other words, two adjacent configuration arrangements 40 share two common electronic device assemblies 42, and the first sectors 441 and the second sectors 442 of the data center 4 are interlaced to form a hive topology.

When the data center 4 is operating, the heat airflow H generated by the configuration arrangement 40a which is adjacent to the electronic device assembly 42 in the first sector 441 is discharged to the first sector 441 and entered the air conditioner 41 through the intake 410a. Afterwards, the heat airflow H exchanges heat to generate a cool airflow C which is discharged to the second sector 442 through the outtake 410b. The cool airflow C in the second sector 442 may enter the electronic device assembly 42 adjacent to the second sector 442 through the air inlet 420b. As the second sector of the configuration arrangements 40a is adjacent to the first sector 441 of the configuration arrangements 40b and share a common electronic device assembly 42 with the configuration arrangements 40b, part of the cool airflow C entering the electronic device assembly 42 may dissipate heat and be transformed into a heat airflow H, which is discharged to the first sector 441 of the configuration arrangements 40b. Also, the heat airflow H generated by the electronic device assembly 42 of the configuration arrangements 40b which is adjacent to the first sector 441 may exchange heat with the air conditioner to generate a cool airflow C, which is in turn discharged to the second sector 442. The cool airflow C is for use by the electronic device assembly 42 of the configuration arrangements 40b which is adjacent to the second sector 442. Therefore, an airflow circulation may be created among the configuration arrangements 40 in the data center 4, thereby shortening the circulation path of the airflow. Also, as the distance between the electronic device assembly 42 and the air conditioner 41 is uniform, the efficiency of the air conditioner 41 is enhanced.

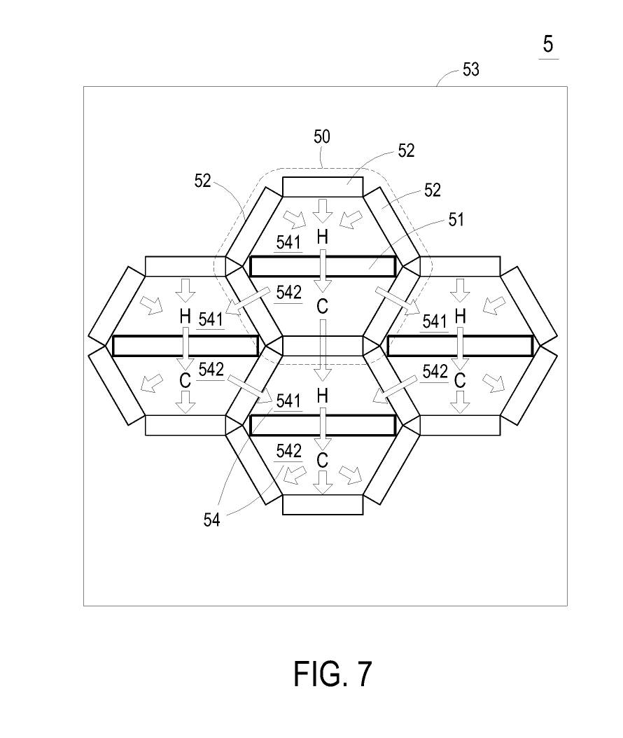

Referring to FIG. 7, the top view of the data center according to a fourth embodiment of the invention is shown. The data center 5 includes a compartment 53 and a plurality of configuration arrangements 50 of electronic device assemblies and air conditioners. In the present embodiment, each configuration arrangement 50 of electronic device assemblies and air conditioners is substantially similar to the configuration arrangement shown in FIG. 5. However, the sixth electronic device assemblies 52 of FIG. 7 are mounted around to form a block 54 which is shaped as a hexagon. Also, the air conditioner 51 which has a length substantially longer than the length of the electronic device assembly 52 is mounted in the block 54, thereby partitioning the block into a first sector 541 and a second sector 542 which are both shaped as a trapezoid. The first sectors 541 and the second sectors 542 in the data center 5 are interlaced. The circulation of the heat airflow H and the cool airflow C are the same as described above.

It can be known from the above descriptions that the configuration arrangements of the electronic device assemblies and air conditioners of the invention may have various embodiments. For example, the sector defined by the electronic device assemblies and air conditioners may be shaped as a regular triangle (as shown in FIG. 2), an isosceles triangle (as shown in FIG. 4A), a rectangle (as shown in FIG. 5), or a trapezoid (as shown in FIG. 7). In other words, the invention covers a wide range of embodiments as follows. A plurality of electronic device assemblies may be mounted around to form a block and an air conditioner partitions the block into a first sector and a second sector which are both substantially shaped as a polygon, in which the intake and the outtake of the air conditioner are respectively configured to face the first sector and the second sector. Also, the electronic device assemblies adjacent to the first sector face the first sector with their air outlets and the electronic device assemblies adjacent to the second sector face the second sector with their air inlets. Also, the configuration unit may have different configurations. For example, the configuration unit involved with in the embodiments of FIGS. 2 and 5 includes two electronic device assemblies and a shared air conditioner. In alternative embodiments, the configuration unit may include two electronic device assemblies and an air conditioner in which one of the electronic device assemblies is a shared electronic device assembly. Moreover, the data center includes a plurality of first sectors and a plurality of second sectors. However, the data center may change the number of the first sectors and the second sectors. In other words, the invention should encompass the variants where the electronic device assemblies and air conditioner are configured to interlace the first sectors and the second sectors.

While the invention has been described in terms of what are presently considered to be the most practical and preferred embodiments, it is to be understood that the present invention need not be restricted to the disclosed embodiment. On the contrary, it is intended to cover various modifications and similar configuration arrangements included within the spirit and scope of the appended claims which are to be accorded with the broadest interpretation so as to encompass all such modifications and similar structures. Therefore, the above description and illustration should not be taken as limiting the scope of the invention which is defined by the appended claims.

What is claimed is:

1. A configuration arrangement of electronic device assemblies and air conditioners for use in a data center, comprising:
an air conditioner having an intake and an outtake respectively mounted on opposite sides of the air conditioner; and
a plurality of electronic device assemblies mounted around to form a block, wherein each electronic device assembly includes an air inlet and an air outlet;
wherein the air conditioner is mounted in the block and partitions the block into a first sector and a second sector which are both substantially shaped as a polygon, the intake and the outtake respectively face the first sector and the second sector, and the electronic device assemblies adjacent to the first sector is configured to face the first sector with air outlets thereof and the electronic device assemblies adjacent to the second sector is configured to face the second sector with air inlets thereof.

2. The configuration arrangement according to claim 1 wherein as the electronic device assemblies adjacent to the first sector discharge a heat airflow to the first sector through the air outlet, and the air conditioner receives the heat airflow through the intake to exchange heat and discharge a cool airflow to the second sector through the outtake, and the electronic device assemblies adjacent to the second sector receives the cool airflow through the air inlet.

3. The configuration arrangement according to claim 1 wherein the air conditioner is mounted in the block and partition the block into the first sector and the second sector which are both shaped as a triangle.

4. The configuration arrangement according to claim 1 wherein the air conditioner is mounted in the block and partition the block into the first sector and the second sector which are both shaped as a rectangle.

5. The configuration arrangement according to claim 1 wherein the air conditioner is mounted in the block and partition the block into the first sector and the second sector which are both shaped as a trapezoid.

6. The configuration arrangement according to claim 1 wherein each electronic device assembly includes a plurality of racks and a plurality of electronic devices accommodated in the racks.

7. The configuration arrangement according to claim 1 wherein the air conditioner is a side-blown air conditioner.

8. A configuration unit for use in a configuration arrangement of electronic device assemblies and air conditioners, comprising:
an air conditioner including an intake and an outtake respectively mounted on opposite sides of the air conditioner;
a plurality of electronic device assemblies mounted around the intake or the outtake of the air conditioner for forming a sector with the air conditioner, in which the sector is substantially shaped as a polygon and each electronic device assembly includes an air inlet and an air outlet;
wherein when the electronic device assemblies are mounted around the intake of the air conditioner, the electronic device assemblies face the sector with the air outlet of the electronic device assemblies, and when the electronic device assemblies are mounted around the outtake of the air conditioner, the electronic device assemblies face the sector with the air outlet of the electronic device assemblies.

9. A data center, comprising:
a compartment;
a plurality of configuration arrangements of electronic device assemblies and air conditioners mounted in the compartment, each of the configuration arrangement of electronic device assemblies and air conditioners comprising:
a plurality of electronic device assemblies mounted around to form a block;
an air conditioner mounted in the block to partition the block into a first sector and a second sector which are both shaped as a polygon;
wherein any two adjacent configuration arrangement of electronic device assemblies and air conditioners share at least one electronic device assembly, and a plurality of the first sectors and a plurality of the second sectors are interlaced.

10. The data center according to claim 9 wherein each air conditioner includes an intake and an outtake respectively mounted on opposite side of the air conditioner and respectively face the first sector and the second sector.

11. The data center according to claim 9 wherein each electronic device assembly includes an air inlet and a corresponding opposite air outlet and each electronic device assembly faces the first sector with the air outlet and faces the second sector with the air inlet.

12. The data center according to claim 9 wherein each electronic device assembly includes a plurality of racks and a plurality of electronic devices accommodated in the racks.
